(19) United States
(12) Patent Application Publication
(10) Pub. No.: US 2022/0199891 A1
(43) Pub. Date: Jun. 23, 2022

(54) PIEZOELECTRIC ELEMENT AND METHOD FOR PRODUCING THE SAME

(71) Applicant: Murata Manufacturing Co., Ltd., Nagaokakyo-shi (JP)

(72) Inventors: Masayuki SUZUKI, Nagaokakyo-shi (JP); Shinsuke IKEUCHI, Nagaokakyo-shi (JP); Fumiya KUROKAWA, Nagaokakyo-shi (JP); Yutaka KISHIMOTO, Nagaokakyo-shi (JP); Hajime YAMADA, Nagaokakyo-shi (JP); Masato KOBAYASHI, Nagaokakyo-shi (JP)

(21) Appl. No.: 17/691,488

(22) Filed: Mar. 10, 2022

Related U.S. Application Data
(63) Continuation of application No. PCT/JP2020/026382, filed on Jul. 6, 2020.

(30) Foreign Application Priority Data
Sep. 17, 2019 (JP) 2019-168463

(51) Int. Cl. H01L 41/047; H01L 41/187; H01L 41/332; H01L 41/313; H01L 41/293; H01L 41/297

(52) U.S. Cl. CPC H01L 41/0471; H01L 41/187; H01L 41/332; H01L 41/297; H01L 41/0474; H01L 41/293; H01L 41/313

(57) ABSTRACT

A piezoelectric element includes a piezoelectric layer, a first electrode layer, a second electrode layer, and a coupling electrode. At least a portion of the second electrode layer faces the first electrode layer with the piezoelectric layer interposed therebetween. The second electrode layer includes a coupling area. The coupling area meets a through hole in a region of the second electrode layer not facing the first electrode layer. The coupling electrode is on the coupling area. Between the coupling area and the surface of the second electrode layer on the piezoelectric layer side excluding the coupling area, the difference in position is about 5 nm or less.

### CROSS REFERENCE TO RELATED APPLICATIONS

This application claims the benefit of priority to Japanese Patent Application No. 2019-168463 filed on Sep. 17, 2019 and is a Continuation Application of PCT Application No. PCT/JP2020/026382 filed on Jul. 6, 2020. The entire contents of each application are hereby incorporated herein by reference.

### BACKGROUND OF THE INVENTION

### 1. Field of the Invention

The present invention relates to a piezoelectric element and a method for producing a piezoelectric element.

### 2. Description of the Related Art

One publication that discloses a structure of a piezoelectric element is Japanese Unexamined Patent Application Publication No. 2009-302661. The piezoelectric element described in Japanese Unexamined Patent Application Publication No. 2009-302661 includes a silicon substrate, a piezoelectric film, and a conductor film. The piezoelectric film is made of a piezoelectric material, such as aluminum nitride (AlN), and is on the silicon substrate. The conductor film is made of an electrically conductive material and is on the piezoelectric film. The conductor film is on the piezoelectric film and between portions of the piezoelectric film and touches an n-type region of the silicon layer and the piezoelectric film. The AlN film is formed by making the film by reactive magnetron sputtering and patterning it by RIE (reactive ion etching) with a chlorine gas.

The production of a piezoelectric device has involved stacking a piezoelectric layer and an electrode layer (lower electrode) together and then creating a through hole in the piezoelectric layer by etching from the opposite side from the electrode layer. The portion of the electrode layer facing the through hole is etched at the same time as the through hole is created. The known piezoelectric devices, therefore, are disadvantageous in that their electrode layer in reality includes an inevitable depression, and loses its crystallinity as a result, where it meets the through hole. Worse yet, a coupling electrode located inside the through hole joins this low-crystallinity portion of the electrode layer. The resulting incomplete electrical coupling at the bond between the electrode layer and the coupling electrode has occasionally caused open defects.

### SUMMARY OF THE INVENTION

Preferred embodiments of the present invention provide piezoelectric elements each with a reduced occurrence of open defects at a bond between an electrode layer and a coupling electrode.

A piezoelectric element according to a preferred embodiment of the present invention includes a piezoelectric layer, a first electrode layer, a second electrode layer, and a coupling electrode. The piezoelectric layer includes a first surface, a second surface, and a through hole. The second surface faces the first surface. The through hole extends all the way from the first surface to the second surface. The first electrode layer is on the first surface. The second electrode layer is on a second surface side of the piezoelectric layer. At least a portion of the second electrode layer faces the first electrode layer with the piezoelectric layer interposed therebetween. The second electrode layer includes a coupling area. The coupling area meets the through hole in a region of the second electrode layer not facing the first electrode layer. The coupling electrode is on the coupling area. Between the coupling area and a surface of the second electrode layer on a piezoelectric layer side excluding the coupling area, a difference in position is about 5 nm or less.

A piezoelectric element according to a preferred embodiment of the present invention includes a piezoelectric layer, a first electrode layer, a second electrode layer, and a coupling electrode. The piezoelectric layer includes a first surface, a second surface, and a through hole. The second surface faces the first surface. The through hole extends all the way from the first surface to the second surface. The first electrode layer is on the first surface. The second electrode layer is on a second surface side of the piezoelectric layer. At least a portion of the second electrode layer faces the first electrode layer with the piezoelectric layer interposed therebetween. The second electrode layer includes a coupling area. The coupling area meets the through hole in a region of the second electrode layer not facing the first electrode layer. The coupling electrode is on the coupling area. The through hole widens from the first surface towards the second surface.

A method for producing a piezoelectric element according to a preferred embodiment of the present invention includes making a depression in a piezoelectric substrate, forming a piezoelectric layer, placing a second electrode layer, and placing a first electrode layer. The piezoelectric substrate includes a first primary surface and a second primary surface facing the first primary surface. In the making a depression in a piezoelectric substrate, the depression is made on a second primary surface side by etching. In the forming a piezoelectric layer, the piezoelectric substrate is ground from a first primary surface side and then polished to expose a first surface and at the same time create a through hole defined by an inner surface of the depression by removing a bottom of the depression. The piezoelectric layer includes a first surface, a second surface, and the through hole. The second surface faces the first surface. The through hole extends all the way from the first surface to the second surface. In placing a second electrode layer, a second electrode layer is placed on a second surface side of the piezoelectric layer such that at least a portion of the second electrode layer meets the through hole. In the placing a first electrode layer, a first electrode layer is laid on a first surface side of the piezoelectric layer such that at least a portion of the first electrode layer faces the second electrode layer with the piezoelectric layer interposed therebetween.

According to preferred embodiments of the present invention, the occurrence of open defects at a bond between an electrode layer and a coupling electrode are able to be reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan diagram illustrating a piezoelectric element according to Preferred Embodiment 1 of the present invention.

FIG. 2 is a cross-sectional view of the piezoelectric element in FIG. 1 in the direction of the arrows of line II-II.

FIG. 3 is a cross-sectional view of a piezoelectric element according to Preferred Embodiment 1 of the present invention in a production process thereof, illustrating a piezoelectric substrate with a depression made therein.

FIG. 4 is a cross-sectional view of a piezoelectric element according to Preferred Embodiment 1 of the present invention in a production process thereof, illustrating a prepared multilayer substrate including a second electrode layer.

FIG. 5 is a cross-sectional view of a piezoelectric element according to Preferred Embodiment 1 of the present invention in a production process thereof, illustrating a piezoelectric substrate bonded to a multilayer substrate including a second electrode layer.

FIG. 6 is a cross-sectional view of a piezoelectric element according to Preferred Embodiment 1 of the present invention in a production process thereof, illustrating a piezoelectric layer formed by scraping a piezoelectric substrate.

FIG. 7 is a cross-sectional view of a piezoelectric element according to Preferred Embodiment 1 of the present invention in a production process thereof, illustrating a first electrode layer being placed.

FIG. 8 is a cross-sectional view of a piezoelectric element according to Preferred Embodiment 1 of the present invention in a production process thereof, illustrating coupling electrodes being placed.

FIG. 9 is a cross-sectional view of a piezoelectric element according to Preferred Embodiment 2 of the present invention in a production process thereof, illustrating coupling electrodes placed on a second electrode layer.

FIG. 10 is a cross-sectional view of a piezoelectric element according to Preferred Embodiment 2 of the present invention in a production process thereof, illustrating a piezoelectric substrate bonded to a multilayer substrate including a second electrode layer.

FIG. 11 is a cross-sectional view of a piezoelectric element according to Preferred Embodiment 2 of the present invention in a production process thereof, illustrating a piezoelectric layer formed by scraping a piezoelectric substrate.

FIG. 12 is a cross-sectional view of a piezoelectric element according to Preferred Embodiment 2 of the present invention in a production process thereof, illustrating a first electrode layer being placed.

FIG. 13 is a cross-sectional diagram illustrating a piezoelectric element according to Preferred Embodiment 3 of the present invention.

FIG. 14 is a cross-sectional view of a piezoelectric element according to Preferred Embodiment 3 of the present invention in a production process thereof, illustrating a through hole plugged with a coupling electrode.

FIG. 15 is a cross-sectional diagram illustrating a piezoelectric element according to Preferred Embodiment 4 of the present invention.

FIG. 16 is a cross-sectional view of view of a piezoelectric element according to Preferred Embodiment 4 of the present invention in a production process thereof, illustrating a piezoelectric substrate with a bonding layer laid thereon.

FIG. 17 is a cross-sectional view of a piezoelectric element according to Preferred Embodiment 4 of the present invention in a production process thereof, illustrating a second bonding layer of a multilayer bonding layer about to be bonded to a first bonding layer.

FIG. 18 is a cross-sectional view of a piezoelectric element according to Preferred Embodiment 4 of the present invention in a production process thereof, illustrating a bonding layer on a piezoelectric substrate bonded to a multilayer substrate including a second electrode layer.

FIG. 19 is a cross-sectional view of a piezoelectric element according to Preferred Embodiment 4 of the present invention in a production process thereof, illustrating a piezoelectric layer formed by scraping a piezoelectric substrate.

FIG. 20 is a cross-sectional view of a piezoelectric element according to Preferred Embodiment 4 of the present invention in a production process thereof, illustrating a first electrode layer being placed.

FIG. 21 is a cross-sectional view of a piezoelectric element according to Preferred Embodiment 4 of the present invention in a production process thereof, illustrating coupling electrodes being placed.

FIG. 22 is a cross-sectional diagram illustrating a piezoelectric element according to Preferred Embodiment 5 of the present invention.

FIG. 23 is a cross-sectional diagram illustrating a piezoelectric element according to Preferred Embodiment 6 of the present invention.

FIG. 24 is a cross-sectional view of a piezoelectric element according to Preferred Embodiment 6 of the present invention in a production process thereof, illustrating a second electrode layer placed on a multilayer substrate.

FIG. 25 is a cross-sectional view of a piezoelectric element according to Preferred Embodiment 6 of the present invention in a production process thereof, illustrating a piezoelectric substrate bonded to a second electrode layer on a multilayer substrate.

FIG. 26 is a cross-sectional view of a piezoelectric element according to Preferred Embodiment 6 of the present invention in a production process thereof, illustrating a piezoelectric layer formed by scraping a piezoelectric substrate.

FIG. 27 is a cross-sectional view of a piezoelectric element according to Preferred Embodiment 6 of the present invention in a production process thereof, illustrating a first electrode layer being placed.

FIG. 28 is a cross-sectional view of a piezoelectric element according to Preferred Embodiment 6 of the present invention in a production process thereof, illustrating coupling electrodes being placed.

FIG. 29 is a cross-sectional diagram illustrating a piezoelectric element presented in Preferred Embodiment 7 of the present invention.

FIG. 30 is a cross-sectional diagram illustrating a piezoelectric element presented in Preferred Embodiment 8 of the present invention.

FIG. 31 is a cross-sectional view of a piezoelectric element according to Preferred Embodiment 8 of the present invention in a production process thereof, illustrating a second bonding layer of a multilayer bonding layer about to be bonded to a first bonding layer.

FIG. 32 is a cross-sectional view of a piezoelectric element according to Preferred Embodiment 8 of the present invention in a production process thereof, illustrating a bonding layer on a piezoelectric substrate bonded to a second electrode layer on a multilayer substrate.

FIG. 33 is a cross-sectional view of a piezoelectric element according to Preferred Embodiment 8 of the present invention in a production process thereof, illustrating a piezoelectric layer formed by scraping a piezoelectric substrate.

FIG. 34 is a cross-sectional view of a piezoelectric element according to Preferred Embodiment 8 of the present invention in a production process thereof, illustrating a first electrode layer being placed.

FIG. 35 is a cross-sectional view of a piezoelectric element according to Preferred Embodiment 8 of the present invention in a production process thereof, illustrating coupling electrodes being placed.

FIG. 36 is a cross-sectional diagram illustrating a piezoelectric element according to Preferred Embodiment 9 of the present invention.

### DETAILED DESCRIPTION OF THE PREFERRED EMBODIMENTS

The following describes piezoelectric elements according to preferred embodiments of the present invention with reference to drawings. In the following description of preferred embodiments, the same or equivalent structural elements in different drawings are identified by the same numerals and described only once.

### Preferred Embodiment 1

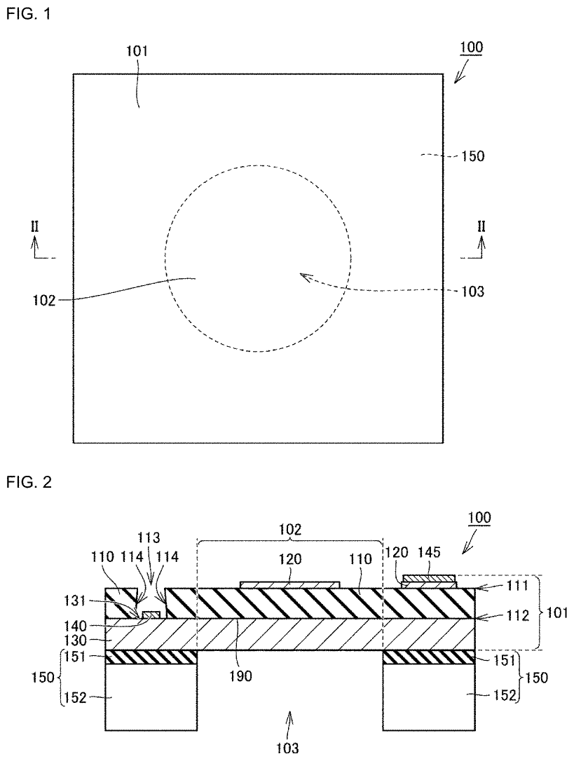

FIG. 1 is a schematic plan diagram illustrating a piezoelectric element according to Preferred Embodiment 1 of the present invention. FIG. 2 is a cross-sectional view of the piezoelectric element in FIG. 1 in the direction of the arrows of line II-II.

As illustrated in FIGS. 1 and 2, a piezoelectric element 100 according to Preferred Embodiment 1 of the present invention includes a piezoelectric layer 110, a first electrode layer 120, a second electrode layer 130, a coupling electrode 140, an outer coupling electrode 145, and a base 150.

As illustrated in FIG. 2, the piezoelectric layer 110 includes a first surface 111, a second surface 112, and a through hole 113. The second surface 112 is on the opposite side from the first surface 111 and faces the first surface 111. The through hole 113 extends all the way from the first surface 111 to the second surface 112. The through hole 113 widens from the first surface 111 towards the second surface 112. Specifically, for example, the through hole 113 widens continuously from the first surface 111 towards the second surface 112.

In the present preferred embodiment, the piezoelectric layer 110 is a layer of, for example, an alkali niobate or alkali tantalate compound. In the present preferred embodiment, the alkali metal(s) in the alkali niobate or alkali tantalate compound is, for example, at least one of lithium, rubidium, or cesium. For example, the piezoelectric layer 110 is a layer of lithium niobate (LiNbO₃) or lithium tantalate (LiTaO₃). In the present preferred embodiment, the piezoelectric layer 110 is a single-crystal layer.

The first electrode layer 120 is on the first surface 111 of the piezoelectric layer 110. There may be an adhesion layer between the first electrode layer 120 and the piezoelectric layer 110. The first electrode layer 120 is a layer of, for example, a metal, such as Al or Pt. The adhesion layer is a layer of, for example, Ti or NiCr.

The second electrode layer 130 is on the second surface 112 side of the piezoelectric layer 110. At least a portion of the second electrode layer 130 faces the first electrode layer 120 with the piezoelectric layer 110 interposed therebetween. In the present preferred embodiment, the second electrode layer 130 faces the first electrode layer 120 only with the piezoelectric layer 110 and a layer of native oxide film, described later, of the second electrode layer 130 interposed therebetween. That is, the second electrode layer 130 is coupled to the second surface 112 of the piezoelectric layer 110.

The second electrode layer 130 meets the through hole 113. The second electrode layer 130 includes a coupling area 131. On the second electrode layer 130, the coupling area 131 meets the through hole 113 in a region not facing the first electrode layer 120. Between the position of the coupling area 131 and that of the surface of the second electrode layer 130 on the piezoelectric layer side 110 excluding the coupling area 131, the difference in the direction perpendicular or substantially perpendicular to the first surface 111 is, for example, about 5 nm or less. In other words, when the surface of the second electrode layer 130 on the piezoelectric layer side 110 excluding the coupling area 131 is defined as a reference plane, the coupling area 131 is, for example, within about 5 nm of the reference plane in the direction from the first surface 111 towards the second surface 112. In the present preferred embodiment, furthermore, the piezoelectric layer 110 side of the second electrode layer 130 has a difference in level to ensure the reference plane and the coupling area 131 are spaced apart from each other. In the present preferred embodiment, the difference in level between the reference plane and the coupling area 131 has a height dimension, or a dimension in the direction perpendicular or substantially perpendicular to the first surface 111, of, for example, about 5 nm or less. This difference, a relative position of the coupling area 131 to the reference plane, and height dimension can be checked by cutting the piezoelectric element 100 vertically with respect to the first surface 111 and observing the cross-section directly with a transmission electron microscope (TEM).

The piezoelectric layer 110 side of the second electrode layer 130 excluding the coupling area 131 is covered with a layer of native oxide film. The coupling area 131 of the second electrode layer 130 may be covered with a layer of native oxide film, but preferably is not included at the bond with the coupling electrode 140, which is described later. In the present preferred embodiment, a layer of native oxide film once present on the coupling area 131 has been removed.

The second electrode layer 130 is, for example, primarily silicon. In the present preferred embodiment, the second electrode layer 130 is, for example, primarily single-crystal silicon. More specifically, the second electrode layer 130 is, for example, a layer of single-crystal silicon doped with a chemical element that lowers the electrical resistivity of the second electrode layer 130. For example, the second electrode layer 130 is doped with an element such as boron (B), aluminum (Al), gallium (Ga), phosphorus (P), arsenic (As), or antimony (Sb). In the present preferred embodiment, it is preferable that the electrical resistivity of the material of the second electrode layer 130 is low, specifically about 20 mΩ·cm or less, for example. In the present preferred embodiment, the etching rate for the material of the second electrode layer 130 in reactive ion etching (RIE) with CF₄ gas is higher than that of the material of the piezoelectric layer 110. Specifically, the etching rate for the material of the second electrode layer 130 is, for example, equal to or higher than about 1.5 times that of the material of the piezoelectric layer 110.

In the present preferred embodiment, the layer of native oxide film is, for example, silicon oxide because the second electrode layer 130 is primarily silicon. In the present preferred embodiment, the thickness of the native oxide film is, for example, about 1 nm or more and about 2 nm or less.

In the present preferred embodiment, the interface 190 between the second electrode layer 130 and the piezoelectric layer 110 is an interfacial bond formed by surface activated bonding or atomic diffusion bonding, for example.

In the present preferred embodiment, the piezoelectric element 100 is an efficient electromechanical transducer because its piezoelectric layer 110 is a single crystal and because its second electrode layer 130 is primarily single-crystal silicon.

As illustrated in FIG. 2, the coupling electrode 140 is on the coupling area 131, which meets the through hole 113, of the second electrode layer 130. In the present preferred embodiment, the coupling electrode 140 is separate from the inner surface 114 of the through hole 113. The coupling electrode 140 is a piece of, for example, Au. There may be an adhesion layer between the coupling electrode 140 and the second electrode layer 130. The adhesion layer is, for example, Ti or NiCr.

As illustrated in FIG. 2, in the present preferred embodiment, a multilayer body 101 includes at least the piezoelectric layer 110, the first electrode layer 120, and the second electrode layer 130. The multilayer body 101 also includes the coupling electrode 140 and the outer coupling electrode 145. The base 150 supports this multilayer body 101.

As illustrated in FIG. 2, the base 150 is on the second electrode layer 130 side of the multilayer body 101. As illustrated in FIG. 1, the base 150 has a ring shaped in alignment with the periphery of the surface of the multilayer body 101 on the base 150 side when viewed in the direction of stacking of layers in the multilayer body 101.

As illustrated in FIG. 2, in the present preferred embodiment, the base 150 includes, for example, a silicon oxide layer 151 and a base body 152. The silicon oxide layer 151 touches the second electrode layer 130. The base body 152 touches the silicon oxide layer 151 on the opposite side of the silicon oxide layer 151 from the second electrode layer 130. In the present preferred embodiment, the base body 152 is made of, for example, single-crystal silicon, although the material for the base body 152 is not limited thereto.

As illustrated in FIG. 2, there is an opening 103 inside the base 150 when viewed in the direction of stacking of layers in the multilayer body 101. The edge of the opening 103 has a round or substantially round external shape when viewed in the direction of stacking and extends in the direction of stacking, although the external shape of the opening 103 is not limited thereto.

As illustrated in FIGS. 1 and 2, in the present preferred embodiment, the multilayer body 101 includes a membrane section 102 therein. The membrane section 102 coincides with the opening 103 and does not coincide with the base 150 when viewed in the direction of stacking.

The piezoelectric element 100 according to the present preferred embodiment is configured such that applying a voltage across the outer coupling electrode 145 and the coupling electrode 140, illustrated in FIG. 2, will cause a voltage to be applied across the first electrode layer 120 and the second electrode layer 130, illustrated in FIG. 2. As a result, the piezoelectric layer 110, interposed between the first electrode layer 120 and the second electrode layer 130, is driven to bend or warp. As a result, the membrane section 102 is allowed to bend and vibrate greatly in the direction of stacking of layers in the multilayer body 101.

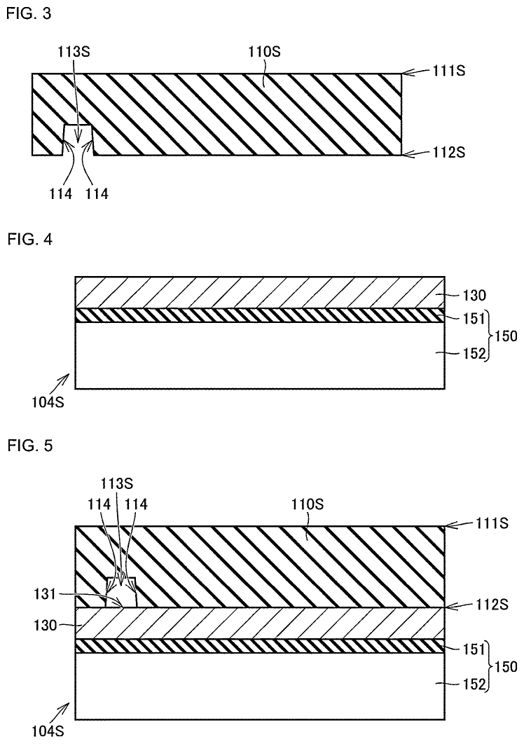

The following describes a non-limiting example of how to produce the piezoelectric element according to Preferred Embodiment 1 of the present invention. A non-limiting example of a method for producing the piezoelectric element 100 according to a preferred embodiment of the present invention includes at least a step of making a depression 113S in a piezoelectric substrate 110S, a step of forming a piezoelectric layer 110, a step of placing a second electrode layer 130, and a step of placing a first electrode layer 120. The states illustrated in FIGS. 3 to 8 are in the same cross-sectional view as in FIG. 2.

FIG. 3 is a cross-sectional view of a piezoelectric element according to Preferred Embodiment 1 of the present invention in a production process thereof, illustrating a piezoelectric substrate with a depression made therein.

As illustrated in FIG. 3, the piezoelectric substrate 110S includes a first primary surface 111S and a second primary surface 112S on the opposite side from the first primary surface 111S. The second primary surface 112S faces the first primary surface 111S. In the step of making a depression 113S in a piezoelectric substrate 110S, the depression 113S is made on the second primary surface 112S side by etching. The etching for making the depression 113S may be dry etching or may be wet etching, for example. As for the depth of the depression 113S, the manufacturer can adjust it to be large enough that the depression 113S can be shaped into a through hole 113 as described later.

FIG. 4 is a cross-sectional view of a piezoelectric element according to Preferred Embodiment 1 of the present invention in a production process thereof, illustrating a prepared multilayer substrate including a second electrode layer. As illustrated in FIG. 4, a multilayer substrate 104S including a second electrode layer 130 and a base 150 is prepared. In the present preferred embodiment, the multilayer substrate 104S is, for example, an SOI (silicon-on-insulator) substrate.

FIG. 5 is a cross-sectional view of a piezoelectric element according to Preferred Embodiment 1 of the present invention in a production process thereof, illustrating a piezoelectric substrate bonded to a multilayer substrate including a second electrode layer. As illustrated in FIG. 5, in the present preferred embodiment, the second electrode layer 130 is bonded to the piezoelectric substrate 110S with the depression 113S made therein. In the present preferred embodiment, furthermore, the piezoelectric substrate 110S is bonded to the multilayer substrate 104S by surface activated bonding or atomic diffusion bonding. As can be seen from this, in the present preferred embodiment, there is no need for a step of placing an extra electrode layer on the substrate because a layer in the substrate can be used as the electrode layer.

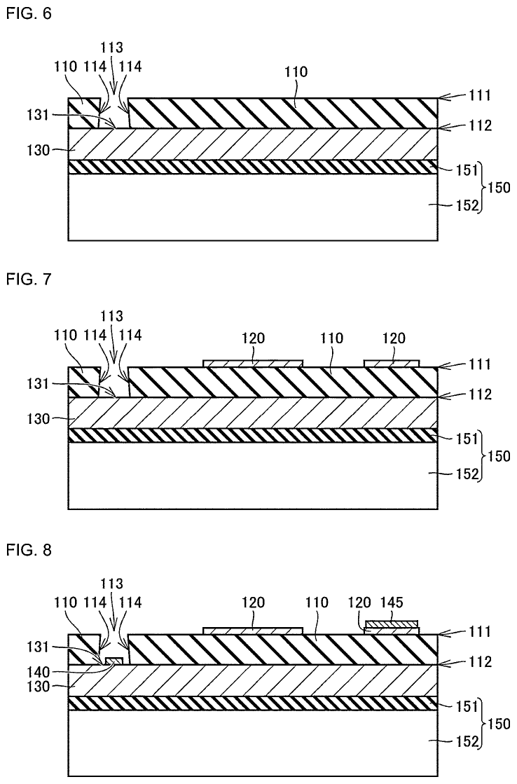

FIG. 6 is a cross-sectional view of a piezoelectric element according to Preferred Embodiment 1 of the present invention in a production process thereof, illustrating a piezoelectric layer formed by scraping a piezoelectric substrate. As illustrated in FIG. 6, in the step of forming a piezoelectric layer 110, the piezoelectric substrate 110S is thinned by grinding, for example, with a grinder, from the first primary surface 111S side and then planarized by polishing, for example, by CMP (chemical mechanical polishing), to expose a first surface 111 and at the same time create a through hole 113 defined by the inner surface 114 of the depression 113S by removing the bottom of the depression 113S.

As can be seen from this, in the production of the piezoelectric element 100 according to the present preferred embodiment, the second electrode layer 130 is placed on the second surface 112 side of the piezoelectric layer 110 such that at least a portion of it meets the through hole 113.

A release layer may be formed beforehand by, for example, ion implantation on the second primary surface 112S side of the piezoelectric substrate 110S. By forming the release layer before bonding the piezoelectric substrate 110S to the second electrode layer 130, the manufacturer can form the piezoelectric layer 110 by removing the release layer after the bonding.

FIG. 7 is a cross-sectional view of a piezoelectric element according to Preferred Embodiment 1 of the present invention in a production process thereof, illustrating a first electrode layer being placed.

As shown, in the step of placing a first electrode layer 120, a first electrode layer 120 is laid on the first surface 111 side of the piezoelectric layer 110 such that at least a portion of it faces the second electrode layer 130 with the piezoelectric layer 110 interposed therebetween. The first electrode layer 120 is formed to have the desired pattern, for example, using deposition and lifting off.

FIG. 8 is a cross-sectional view of a piezoelectric element according to Preferred Embodiment 1 of the present invention in a production process thereof, illustrating coupling electrodes being placed. As illustrated in FIG. 8, a coupling electrode 140 and an outer coupling electrode 145 are formed, for example, using deposition and lifting off. In the present preferred embodiment, the formation of a coupling electrode 140 is preceded by removing a layer of native oxide film on the coupling area 131 of the second electrode layer 130 by etching, for example, such as wet etching. The removal of the layer of native oxide film will ensure that the difference between the position of the coupling area 131 and that of the surface of the second electrode layer 130 on the piezoelectric layer side 110 excluding the coupling area 131 in the direction perpendicular or substantially perpendicular to the first surface 111 is about 5 nm or less, for example because the thickness of the layer of native oxide film is, for example, about 1 nm or more and about 2 nm or less. As long as the thickness of the layer removed by etching is as thin as about 5 nm or less, for example, the contact resistance at the coupling area 131 will not increase significantly, for example, because of an alteration in the quality of the coupling area 131. In the present preferred embodiment, therefore, the second electrode layer 130 has a recessed, including a depression at its coupling area 131, on its piezoelectric layer 110 side because of the removal of a layer of native oxide film, although not illustrated in FIG. 8.

Lastly, the opening 103 of the piezoelectric element 100 according to the present preferred embodiment is created from the opposite side of the base 150 from the second electrode layer 130 by, for example, deep reactive ion etching (deep RIE). In the present preferred embodiment, the formation of the opening 103 is by etching the silicon oxide layer 151. The silicon oxide layer 151, however, does not need to be etched, and a portion of the silicon oxide layer 151 in the direction of stacking of layers in the multilayer substrate 104S may be etched.

Through these steps, a piezoelectric element 100 according to Preferred Embodiment 1 of the present invention as illustrated in FIGS. 1 and 2 is produced.

Overall, for the piezoelectric element 100 according to Preferred Embodiment 1 of the present invention, the second electrode layer 130 includes a coupling area 131. The coupling area 131 meets the through hole 113 in a region of the second electrode layer 130 not facing the first electrode layer 120. The coupling electrode 140 is on the coupling area 131, which meets the through hole 113, of the second electrode layer 130. Between the coupling area 131 and the surface of the second electrode layer 130 on the piezoelectric layer 110 side excluding the coupling area 131, the difference in position is about 5 nm or less, for example.

Due to this, in the present preferred embodiment, the coupling area 131 is not affected by the etching for creating the through hole 113, and, therefore, the aforementioned positional difference is about 5 nm or less, for example. This helps reduce or prevent the second electrode layer 130 from losing its crystallinity in the coupling area 131, and this in turn helps reduce or prevent the occurrence of open defects at the bond between the coupling area 131 of the second electrode 130 and the coupling electrode 140.

The through hole 113 widens from the first surface 111 towards the second surface 112.

This helps reduce the resistivity at the bond between the second electrode layer 130 and the coupling electrode 140. That is, the through hole 113 has a large cross-sectional area at its end on the second surface 112 side as compared to that on the first surface side 111. The manufacturer, therefore, can lower the contact resistance between the second electrode layer 130 and the coupling electrode 140 by increasing the area of coupling between the second electrode layer 130 and the coupling electrode 140.

In particular, if the coupling electrode 140 is formed by lifting off, the production yield of the piezoelectric element 100 improves. In this case incomplete coupling between the coupling electrode 140 and the second electrode layer 130 is less likely because the formation of the coupling electrode 140 is facilitated.

The through hole 113 widens continuously from the first surface 111 towards the second surface 112.

This allows the through hole 113 to be created in few steps compared with if the through hole 113 is created with stepwise inner surfaces.

The coupling electrode 140 is separate from the inner surface 114 of the through hole 113.

This helps reduce cracking in the coupling electrode 140 because the coupling electrode 140 does not touch the corner formed by the inner surface 114 of the through hole 113 and the first surface 111, where stress often concentrates.

In reactive ion etching with CF₄ gas, the etching rate of the material of the second electrode layer 130 is higher than that of the material of the piezoelectric layer 110.

In the present preferred embodiment, the second electrode layer 130 is more susceptible to etching than the piezoelectric layer 110 because of such a difference in etching rate. Nevertheless, the positional difference is about 5 nm or less, for example, which means the coupling area 131 has not been affected by the etching for creating the through hole 113. This helps reduce or prevent the second electrode layer 130 from losing its crystallinity in the coupling area 131, and this in turn helps reduce or prevent the occurrence of open defects at the bond between the coupling area 131 of the second electrode layer 130 and the coupling electrode 140.

The piezoelectric layer 110 includes, for example, an alkali niobate or alkali tantalate compound. The alkali metal(s) in the alkali niobate or alkali tantalate compound is, for example, at least one of lithium, rubidium, or cesium. The second electrode layer 130 is, for example, primarily silicon.

Due to this, the dielectric constant of the piezoelectric layer 110 is relatively low. The electrical impedance of the piezoelectric layer 110, furthermore, is high, which means the voltage applied to the piezoelectric layer 110 is large compared to that applied to the primarily silicon second electrode layer 130. This helps improve the drive efficiency of the piezoelectric element 100.

The piezoelectric layer 110 is, for example a layer of lithium niobate. This helps improve the characteristics of the piezoelectric element 100. The piezoelectric constant of the piezoelectric layer 110 is high compared with if the piezoelectric layer 110 is a layer of another alkali niobate compound or an alkali tantalate compound.

The piezoelectric layer 110 includes, for example, lithium tantalate. This helps improve the characteristics of the piezoelectric element 100, to a lower dielectric constant and therefore a higher electrical impedance of the piezoelectric layer 110. The drive efficiency of the piezoelectric element 100 improves compared with if the piezoelectric layer 110 is a layer of another alkali niobate compound or an alkali tantalate compound.

The second electrode layer 130 is, for example, primarily single-crystal silicon. This improves the strength of bonding between the piezoelectric layer 110 and the second electrode layer 130, thus improving the efficiency of the piezoelectric layer 110 in electromechanical transduction.

The piezoelectric element 100 further includes a base 150 that supports a multilayer body 101 including at least the first electrode layer 120, the piezoelectric layer 110, and the second electrode layer 130. The base 150 is on the second electrode layer 130 side of the multilayer body 101 and has a ring shape in alignment with the periphery of the surface of the multilayer body 101 on the base 150 side when viewed in the direction of stacking of layers in the multilayer body 101.

This allows the driving of the piezoelectric layer 110 to be converted into bending and vibration of a membrane section 102, thus improving the characteristics of the piezoelectric element 100 as a device.

The base 150 includes a silicon oxide layer in contact with the second electrode layer 130. The second electrode layer 130 is a layer of single-crystal silicon doped with a chemical element that lowers the electrical resistivity of the second electrode layer 130.

This allows the manufacturer to couple the second electrode layer 130 and the base 150 simultaneously to the piezoelectric layer 110 using a multilayer substrate, and at the same time improves the current efficiency of the second electrode layer 130.

A non-limiting example of a method for producing a piezoelectric element 100 according to a preferred embodiment of the present invention includes a step of making a depression 113S in a piezoelectric substrate 110S, a step of forming a piezoelectric layer 110, a step of placing a second electrode layer 130, and a step of placing a first electrode layer 120. The piezoelectric substrate 110S includes a first primary surface 111S and a second primary surface 112S that faces the first primary surface 111S. In the step of making a depression 113S in a piezoelectric substrate 110S, the depression 113S is made on the second primary surface 112S side by etching. In the step of forming a piezoelectric layer 110, the piezoelectric substrate 110S is ground from the first primary surface 111S side and then polished to expose a first surface 111 and at the same time create a through hole 113 defined by the inner surface 114 of the depression 113S by removing the bottom of the depression 113S. In the step of placing a second electrode layer 130, a second electrode layer 130 is placed on the second surface 112 side of the piezoelectric layer 110 such that at least a portion of it meets the through hole 113. In the step of placing a first electrode layer 120, a first electrode layer 120 is laid on the first surface 111 side of the piezoelectric layer 110 such that at least a portion of it faces the second electrode layer 130 with the piezoelectric layer 110 interposed therebetween.

As can be seen from this, it is before the second electrode layer 130 is placed on the piezoelectric substrate 110S that a depression 113S corresponding to the through hole 113 is made by etching. The second electrode layer 130, therefore, is not etched when the through hole 113 is created. This reduces or prevents the second electrode layer 130 from losing its crystallinity in the coupling area 131, limits the associated increase in electrical resistivity at the bond between the coupling area 131 of the second electrode layer 130 and the coupling electrode 140, and reduces or prevents the occurrence of open defects at the second electrode layer 130.

Furthermore, the piezoelectric element 100 according to the present preferred embodiment is configured such that in reactive ion etching with CF₄ gas, the etching rate for the material forming the second electrode layer 130 is higher than that of the material forming the piezoelectric layer 110. If the second electrode layer 130 was placed on the piezoelectric substrate 110S first and then the through hole 113 was created by etching, it would result in an overetching of the second electrode layer 130. The overetching would lead to an increased electrical resistivity at the bond due to surface alterations and/or a reduced thickness of the second electrode layer 130. In the present preferred embodiment, however, the second electrode 130 cannot be overetched during the creation of the through hole 113 because the through hole 113 is created in the manner described above. Due to this, in the present preferred embodiment, the increase in electrical resistivity at the bond is limited, and, at the same time, the material of the second electrode layer 130 can be one in which the etching rate is higher than that of the material of the piezoelectric layer 110.

The through hole 113, furthermore, is defined by the inner surface 114 of the depression 113S made by etching the piezoelectric substrate 110S from its second primary surface 112S side, which means the through hole 113 can be shaped as one that, for example, widens from the first surface 111 towards the second surface 112. Due to this, the manufacturer can reduce the contact resistance at the bond between the second electrode layer 130 and the coupling electrode 140 by increasing the area of coupling between the second electrode layer 130 and the coupling electrode 140.

### Preferred Embodiment 2

The following describes a piezoelectric element according to Preferred Embodiment 2 of the present invention. The structure of the piezoelectric element according to Preferred Embodiment 2 of the present invention is the same or substantially the same as that of the piezoelectric element 100 according to Preferred Embodiment 1 of the present invention, but the production of the piezoelectric element according to Preferred Embodiment 2 of the present invention is different from that of the piezoelectric element 100 according to Preferred Embodiment 1 of the present invention. The following description of the piezoelectric element according to Preferred Embodiment 2 of the present invention, therefore, relates only to how to produce it and does not describe the same or substantially the same structural details as in the production of the piezoelectric element 100 according to Preferred Embodiment 1 of the present invention.

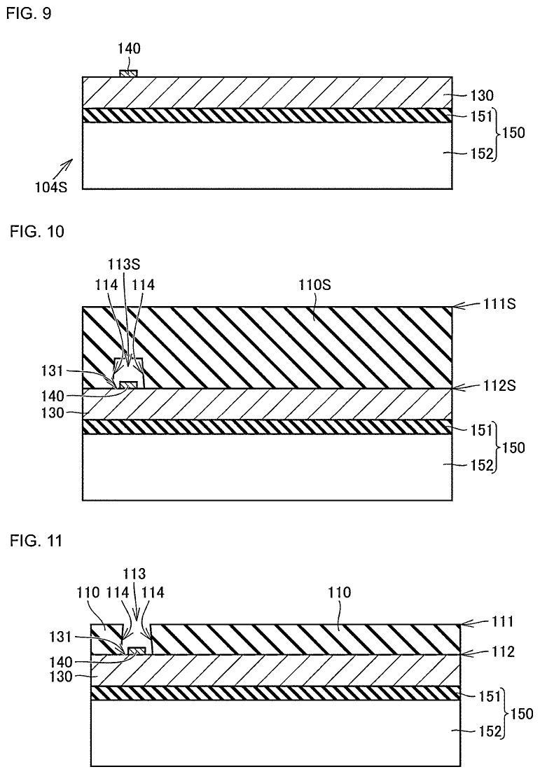

FIG. 9 is a cross-sectional view of a piezoelectric element according to Preferred Embodiment 2 of the present invention in a production process thereof, illustrating coupling electrodes placed on a second electrode layer. As illustrated in FIG. 9, in the production of the piezoelectric element according to Preferred Embodiment 2 of the present invention, the coupling electrode 140 is formed on the second electrode layer 130 before the second electrode layer 130 is placed on the second surface 112 side of the piezoelectric layer 110. The coupling electrode 140 can be formed by methods such as, for example, deposition, sputtering, and plating.

FIG. 10 is a cross-sectional view of a piezoelectric element according to Preferred Embodiment 2 of the present invention in a production process thereof, illustrating a piezoelectric substrate bonded to a multilayer substrate including a second electrode layer. As illustrated in FIG. 10, a piezoelectric substrate 110S with a depression 113S made therein and the second electrode layer 130 are bonded together. The bonding together of the piezoelectric substrate 110S and the second electrode layer 130 is performed such that the inner surface 114 of the depression 113S and the coupling electrode 140 will not touch each other. In the present preferred embodiment, it is preferable to remove the native oxide film on the entire or substantially the entire second electrode layer 130, for example by etching, before forming the coupling electrode 140.

FIG. 11 is a cross-sectional view of a piezoelectric element according to Preferred Embodiment 2 of the present invention in a production process thereof, illustrating a piezoelectric layer formed by scraping a piezoelectric substrate. As illustrated in FIG. 11, a piezoelectric layer 110 is formed in the same or substantially the same manner as in the production of the piezoelectric element 100 according to Preferred Embodiment 1 of the present invention.

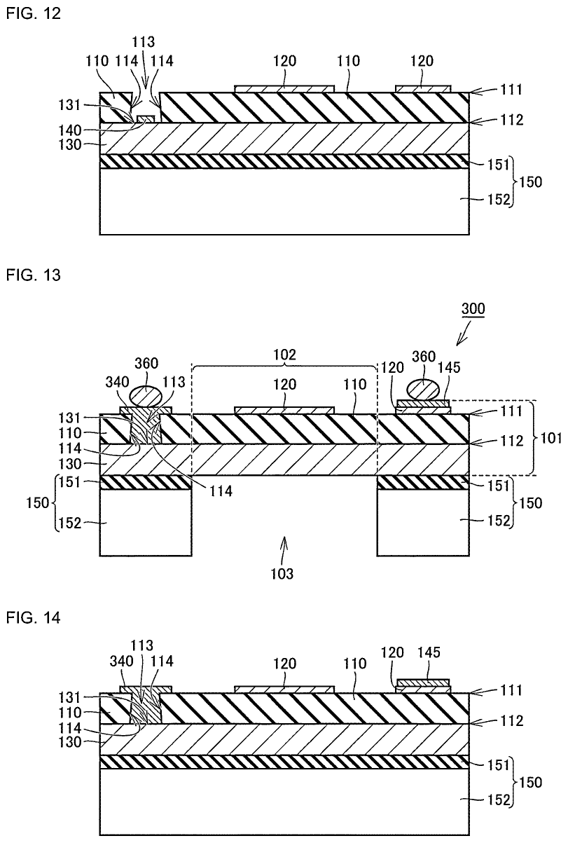

FIG. 12 is a cross-sectional view of a piezoelectric element according to Preferred Embodiment 2 of the present invention in a production process thereof, illustrating a first electrode layer being placed. As illustrated in FIG. 12, a first electrode layer 120 is laid in the same or substantially the same way as in the production of the piezoelectric element 100 according to Preferred Embodiment 1 of the present invention. Lastly, an opening 103 is created in the same or substantially the same way as in the production of the piezoelectric element 100 according to Preferred Embodiment 1 of the present invention.

Through these steps, a piezoelectric element like the piezoelectric element 100 according to Preferred Embodiment 1 of the present invention illustrated in FIGS. 1 and 2 can be produced.

### Preferred Embodiment 3

The following describes a piezoelectric element according to Preferred Embodiment 3 of the present invention. The piezoelectric element according to Preferred Embodiment 3 of the present invention differs from the piezoelectric element 100 according to Preferred Embodiment 1 of the present invention primarily in the structure of the coupling electrode. The following description, therefore, omits a description of the same or substantially the same structural details as for the piezoelectric element 100 according to Preferred Embodiment 1 of the present invention.

FIG. 13 is a cross-sectional diagram illustrating a piezoelectric element according to Preferred Embodiment 3 of the present invention. As illustrated in FIG. 13, the piezoelectric element 300 according to Preferred Embodiment 3 of the present invention includes a through hole 113 plugged with the coupling electrode 340. This helps improve the peel strength of the coupling electrode 340 with respect to the second electrode layer 130, thus improving the reliability of the piezoelectric element 300. The piezoelectric element 300, furthermore, can be compact. In packaging the piezoelectric element 300 by flip-chip bonding, the solder bump 360 can be placed to overlap the through hole 113 when viewed in the direction perpendicular or substantially perpendicular to the first surface 111.

Furthermore, in the present preferred embodiment the through hole 113 widens from the first surface 111 towards the second surface. This further reduces or prevent the coupling electrode 340, stuck in the through hole 113, from separating and detaching the first surface 111.

The following describes how to produce the piezoelectric element 300 according to Preferred Embodiment 3 of the present invention. In producing the piezoelectric element 300 according to Preferred Embodiment 3 of the present invention, a through hole 113 is created as illustrated in FIG. 7, in the same or substantially the same manner as in the production of the piezoelectric element according to Preferred Embodiment 1 of the present invention.

FIG. 14 is a cross-sectional view of a piezoelectric element according to Preferred Embodiment 3 of the present invention in a production process thereof, illustrating a through hole plugged with a coupling electrode. As illustrated in FIG. 14, a coupling electrode 340 and an outer coupling electrode 145 are formed. In the present preferred embodiment, the coupling electrode 340 is formed using plating. This makes the through hole 113 plugged with the coupling electrode 340. The coupling electrode 340 and the outer coupling electrode 145 may be formed simultaneously, or one of the coupling electrode 340 or outer coupling electrode 145 may be formed first, and then the other.

Lastly, an opening 103 is created in the same or substantially the same manner as in the production of the piezoelectric element 100 according to Preferred Embodiment 1 of the present invention. Through these steps, the piezoelectric element 300 according to Preferred Embodiment 3 of the present invention illustrated in FIG. 13 can be produced.

### Preferred Embodiment 4

The following describes a piezoelectric element according to Preferred Embodiment 4 of the present invention. The piezoelectric element according to Preferred Embodiment 4 of the present invention differs from the piezoelectric element 100 according to Preferred Embodiment 1 of the present invention primarily in that it further includes a bonding layer. The following description, therefore, omits description of the same or substantially the same structural details as for the piezoelectric element 100 according to Preferred Embodiment 1 of the present invention.

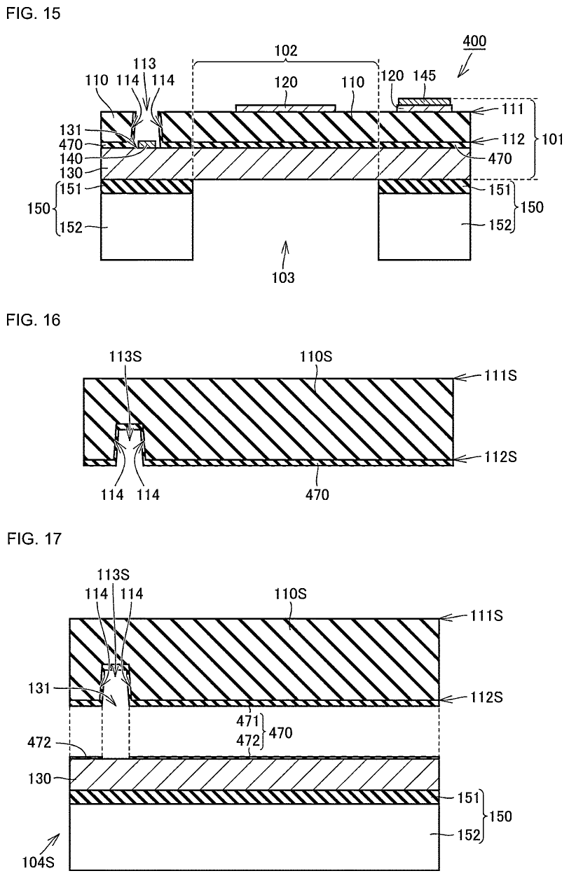

FIG. 15 is a cross-sectional diagram illustrating a piezoelectric element according to Preferred Embodiment 4 of the present invention. As illustrated in FIG. 15, the piezoelectric element 400 according to Preferred Embodiment 4 of the present invention includes a bonding layer 470 between the piezoelectric layer 110 side of the second electrode layer 130 excluding the coupling area 131 and the piezoelectric layer 110. This improves the strength of bonding between the piezoelectric layer 110 and the second electrode layer 130.

In the present preferred embodiment, the bonding layer 470 also covers the inner surface 114 of the through hole 113. This improves the resistance to environmental conditions of the inner surface 114 of the through hole 113.

In the present preferred embodiment, the bonding layer 470 is made of, for example, silicon oxide (SiO₂). This allows the manufacturer to provide an appropriately thick bonding layer 470 between the second electrode layer 130 and the piezoelectric layer 110 considering the dielectric constant of the bonding layer 470. The bonding layer 470 may include metal(s).

The bonding layer 470, furthermore, may include multiple layers, and the multiple layers may include metal layer(s). If the bonding layer 470 includes multiple layers, the portion of the bonding layer 470 in contact with the second electrode layer 130 may be a layer of native oxide film of the second electrode layer 130. The layer of native oxide film is made of, for example, SiO₂.

The following describes how to produce the piezoelectric element according to Preferred Embodiment 4 of the present invention. In producing the piezoelectric element according to Preferred Embodiment 4 of the present invention, a depression 113S is made in a piezoelectric substrate 110S as illustrated in FIG. 3 first, in the same or substantially the same manner as in the production of the piezoelectric element according to Preferred Embodiment 1 of the present invention.

FIG. 16 is a cross-sectional view of a piezoelectric element according to Preferred Embodiment 4 of the present invention in a production process thereof, illustrating a piezoelectric substrate with a bonding layer formed thereon. As illustrated in FIG. 16, a bonding layer 470 is formed over the second primary surface 112S of the piezoelectric substrate and the inner surface 114 and bottom of the depression 113S, for example, by CVD (chemical vapor deposition) or PVD (physical vapor deposition).

If the bonding layer 470 includes multiple layers and if the portion of the bonding layer 470 in contact with the second electrode layer 130 is a layer of native oxide film of the second electrode layer 130, the bonding layer 470 can be formed by placing a first bonding layer as in the placing of a bonding layer 470 described above first and then bonding a second bonding layer, which is the layer of native oxide film, to the first bonding layer. FIG. 17 is a cross-sectional view of a piezoelectric element according to Preferred Embodiment 4 of the present invention in a production process thereof, illustrating a second bonding layer of a multilayer bonding layer about to be bonded to a first bonding layer. As illustrated in FIG. 17, a second bonding layer 472, which is a layer of native oxide film of the second electrode layer 130, is bonded to a first bonding layer 471, which has already been laid. In bonding the first and second bonding layers 471 and 472 together, the portion of the second electrode layer 130, which is in the multilayer substrate 104S, that will aligned with the depression 113S in the piezoelectric substrate 110S is cleared of the layer of native oxide film beforehand so that the second bonding layer 472 will not be aligned with the depression 113S.

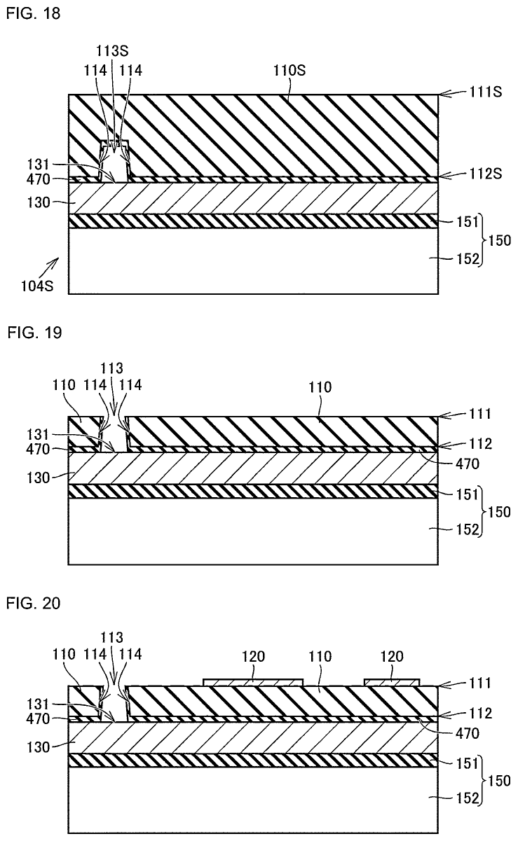

FIG. 18 is a cross-sectional view of a piezoelectric element according to Preferred Embodiment 4 of the present invention in a production process thereof, illustrating a bonding layer on a piezoelectric substrate bonded to a multilayer substrate including a second electrode layer. As illustrated in FIG. 18, the second electrode layer 130 and the piezoelectric substrate 110S are bonded together by, for example, surface activated bonding or atomic diffusion bonding with the bonding layer 470 interposed therebetween. If the bonding layer 470 includes first and second bonding layers 471 and 472 as in FIG. 16, the second electrode layer 130 and the piezoelectric substrate 110S are bonded together with the first and second bonding layers 471 and 472 interposed therebetween.

FIG. 19 is a cross-sectional view of a piezoelectric element according to Preferred Embodiment 4 of the present invention in a production process thereof, illustrating a piezoelectric layer formed by scraping a piezoelectric substrate. As illustrated in FIG. 19, the bottom, covered with the bonding layer 470, of the depression 113S is removed together with the bonding layer 470.

FIG. 20 is a cross-sectional view of a piezoelectric element according to Preferred Embodiment 4 of the present invention in a production process thereof, illustrating a first electrode layer being placed. As illustrated in FIG. 20, a first electrode layer 120 is placed on the first surface 111 side of the piezoelectric layer 110.

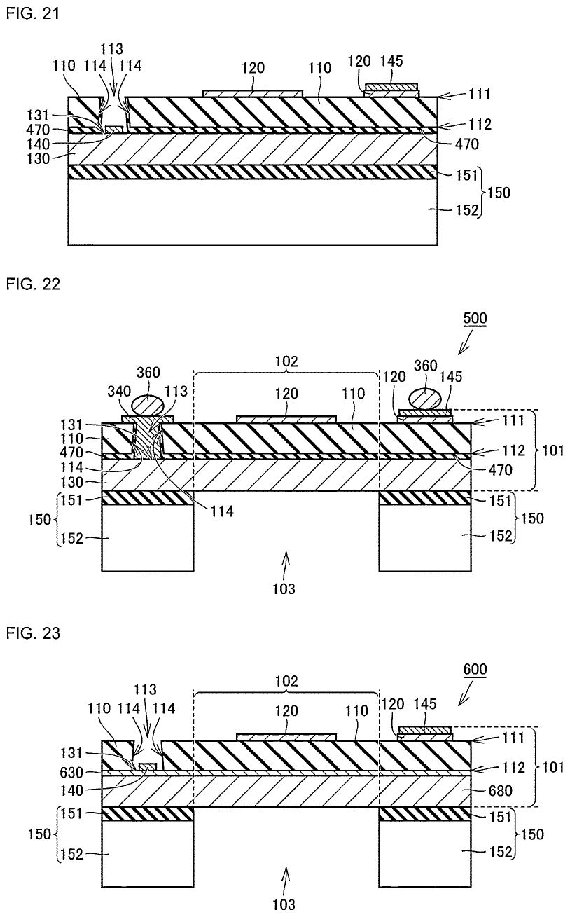

FIG. 21 is a cross-sectional view of a piezoelectric element according to Preferred Embodiment 4 of the present invention in a production process thereof, illustrating coupling electrodes being placed. As illustrated in FIG. 21, a coupling electrode 140 and an outer coupling electrode 145 are formed in the same or substantially the same manner as for the piezoelectric element 100 according to Preferred Embodiment 1 of the present invention. Then, lastly, an opening 103 is formed to finish the piezoelectric element 400 according to Preferred Embodiment 4 of the present invention illustrated in FIG. 15.

### Preferred Embodiment 5

The following describes a piezoelectric element according to Preferred Embodiment 5 of the present invention. The piezoelectric element according to Preferred Embodiment 5 of the present invention differs from the piezoelectric element 400 according to Preferred Embodiment 4 of the present invention primarily in the structure of the coupling electrode. The following description, therefore, omits description of the same or substantially the same structural details as for the piezoelectric element 400 according to Preferred Embodiment 4 of the present invention.

FIG. 22 is a cross-sectional diagram illustrating a piezoelectric element according to Preferred Embodiment 5 of the present invention. The piezoelectric element 500 according to Preferred Embodiment 5 of the present invention includes a through hole 113 plugged with the coupling electrode 340, similar to the piezoelectric element 300 according to Preferred Embodiment 3 of the present invention. This improves the peel strength of the coupling electrode 340 with respect to the second electrode layer 130.

### Preferred Embodiment 6

The following describes a piezoelectric element according to Preferred Embodiment 6 of the present invention. The piezoelectric element according to Preferred Embodiment 6 of the present invention differs from the piezoelectric element 100 according to Preferred Embodiment 1 of the present invention primarily in that the second electrode layer is separate from a multilayer substrate. The following description, therefore, omits description of the same or substantially the same structural details as for the piezoelectric element 100 according to Preferred Embodiment 1 of the present invention.

FIG. 23 is a cross-sectional diagram illustrating a piezoelectric element according to Preferred Embodiment 6 of the present invention. As illustrated in FIG. 23, the piezoelectric element 600 according to Preferred Embodiment 6 of the present invention includes, for example, a lithium niobate piezoelectric layer 110. The second electrode layer 630 includes a metallic material. The second electrode layer 630 is a layer of, for example, Al or Pt.

In the present preferred embodiment, the piezoelectric layer 110 is made with lithium niobate, for which the etching rate is lower than for the metallic material for the second electrode layer 630. When the through hole 113 is created, however, the second electrode 630 is not etched. This reduces or prevents the second electrode layer 630 from losing its crystallinity, thus reducing or preventing the occurrence of open defects caused by incomplete electrical coupling at the bond between the coupling electrode 140 and the second electrode layer 630 in the coupling area 131.

In the present preferred embodiment, a silicon layer 680 is provided on the opposite surface of the second electrode layer 630 from the piezoelectric layer 110. This improves current efficiency because not only the second electrode layer 630 but also the silicon layer 680 defines and functions as an electrode layer.

As can be seen from this, in the present preferred embodiment, the multilayer body 101 further includes, for example, a silicon layer 680. The base 150 is on the silicon layer 680 side of the multilayer body 101.

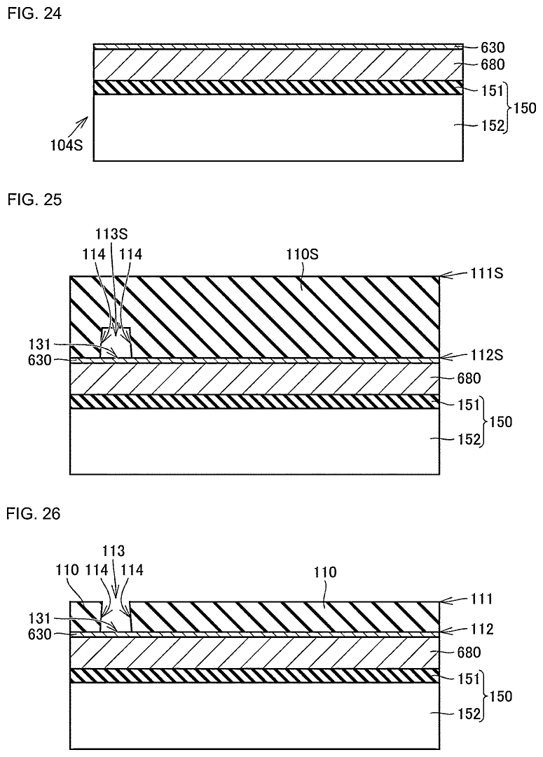

The following describes how to produce the piezoelectric element according to Preferred Embodiment 6 of the present invention. FIG. 24 is a cross-sectional view of a piezoelectric element according to Preferred Embodiment 6 of the present invention in a production process thereof, illustrating a second electrode layer placed on a multilayer substrate. As illustrated in FIG. 24, in the present preferred embodiment, the multilayer substrate 104S includes a silicon layer 680 and a base 150. On the silicon layer 680 of the multilayer substrate 104S a second electrode layer 630 is formed, for example, by CVD or PVD.

FIG. 25 is a cross-sectional view of a piezoelectric element according to Preferred Embodiment 6 of the present invention in a production process thereof, illustrating a piezoelectric substrate bonded to a second electrode layer on a multilayer substrate. As illustrated in FIG. 25, a piezoelectric substrate 110S with a depression 113S made therein, illustrated in FIG. 3, is bonded onto the second electrode layer 630 by, for example, surface activated bonding or atomic diffusion bonding.

FIG. 26 is a cross-sectional view of a piezoelectric element according to Preferred Embodiment 6 of the present invention in a production process thereof, illustrating a piezoelectric layer formed by scraping a piezoelectric substrate. As illustrated in FIG. 26, a piezoelectric layer 110 is formed by thinning the piezoelectric substrate 110S by grinding, for example, with a grinder, and planarizing the surface by polishing, for example, by CMP, as in the production of the piezoelectric element 100 according to Preferred Embodiment 1 of the present invention. As can be seen from this, in the present preferred embodiment, it is before the second electrode layer 630 is formed on the piezoelectric substrate 110S that a depression 113S corresponding to the through hole 113 is made by etching. The second electrode layer 630, therefore, is not etched when the through hole 113 is created. This reduces or prevents the second electrode layer 630 from becoming disordered in the coupling area 131, limits the associated increase in electrical resistivity at the bond between the coupling area 131 of the second electrode layer 630 and the coupling electrode 140, and in turn reduces or prevents the occurrence of open defects at the second electrode layer 630.

If the piezoelectric element 600 according to the present preferred embodiment includes, for example, a lithium niobate piezoelectric layer 110 and if the etching rate for the metallic material forming the second electrode layer 630 is higher than that for lithium niobate as in the foregoing, forming the second electrode layer 630 on the piezoelectric substrate 110S first and then creating the through hole 113 by etching would result in an overetching of the second electrode layer 630. The overetching would lead to an increased electrical resistivity at the bond because of surface alteration and/or a reduced thickness of the second electrode layer 630. In the present preferred embodiment, however, the second electrode 630 cannot be overetched during the creation of the through hole 113 because the through hole 113 is created in the manner described above. Due to this, in the present preferred embodiment, the increase in electrical resistivity at the bond is limited, and, at the same time, the second electrode layer 630 can be a metallic material for which the etching rate is higher than that for lithium niobate.

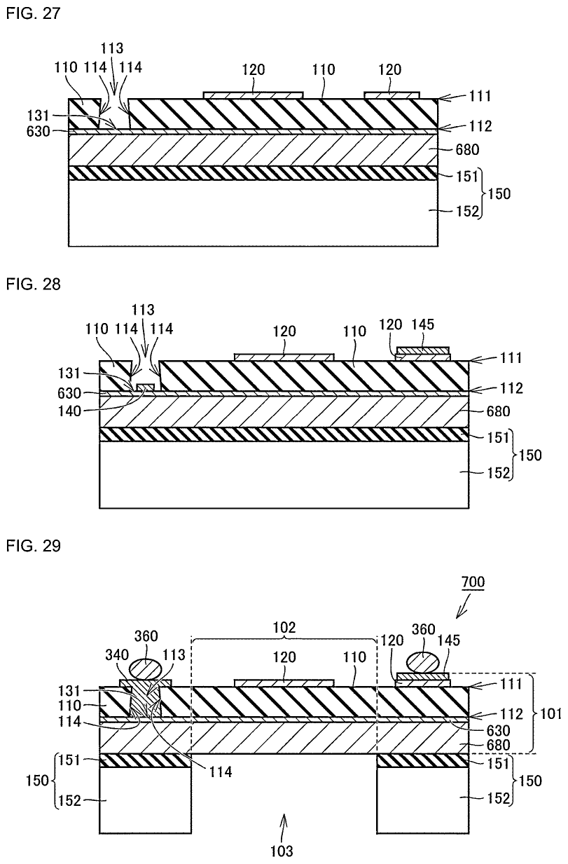

FIG. 27 is a cross-sectional view of a piezoelectric element according to Preferred Embodiment 6 of the present invention in its production process, illustrating a first electrode layer placed. As illustrated in FIG. 27, a first electrode layer 120 is placed in the same way as in the production of the piezoelectric element 100 according to Preferred Embodiment 1 of the present invention.

FIG. 28 is a cross-sectional view of a piezoelectric element according to Preferred Embodiment 6 of the present invention in its production process, illustrating coupling electrodes placed. As illustrated in FIG. 28, a coupling electrode 140 and an outer coupling electrode 145 are formed. In the present preferred embodiment, the coupling area 131 may be covered with a native oxide film, but preferably is not covered with the native oxide film at the bond with the coupling electrode 140. In the present preferred embodiment, it is preferable to remove the native oxide film on the entire or substantially the entire coupling area 131, for example, by etching, before forming the coupling electrode 140. Then an opening 103 is created last, finishing the piezoelectric element 600 according to Preferred Embodiment 6 of the present invention illustrated in FIG. 23.

### Preferred Embodiment 7

The following describes a piezoelectric element according to Preferred Embodiment 7 of the present invention. The piezoelectric element according to Preferred Embodiment 7 of the present invention differs from the piezoelectric element 600 according to Preferred Embodiment 6 of the present invention primarily in the structure of the coupling electrode. The following description, therefore, omits description of the same or substantially the same structural details as for the piezoelectric element 600 according to Preferred Embodiment 6 of the present invention.

FIG. 29 is a cross-sectional diagram illustrating a piezoelectric element presented in Preferred Embodiment 7 of the present invention. The piezoelectric element 700 according to Preferred Embodiment 7 of the present invention includes a through hole 113 plugged with the coupling electrode 340, as in the piezoelectric element 300 according to Preferred Embodiment 3 of the present invention. This improves the peel strength of the coupling electrode 340 with respect to the second electrode layer 630.

### Preferred Embodiment 8

The following describes a piezoelectric element according to Preferred Embodiment 8 of the present invention. The piezoelectric element according to Preferred Embodiment 8 of the present invention differs from the piezoelectric element 400 according to Preferred Embodiment 4 of the present invention primarily in that a second electrode layer is separate from a multilayer substrate. The following description, therefore, omits description of the same or substantially the same structural details as for the piezoelectric element 400 according to Preferred Embodiment 4 of the present invention.

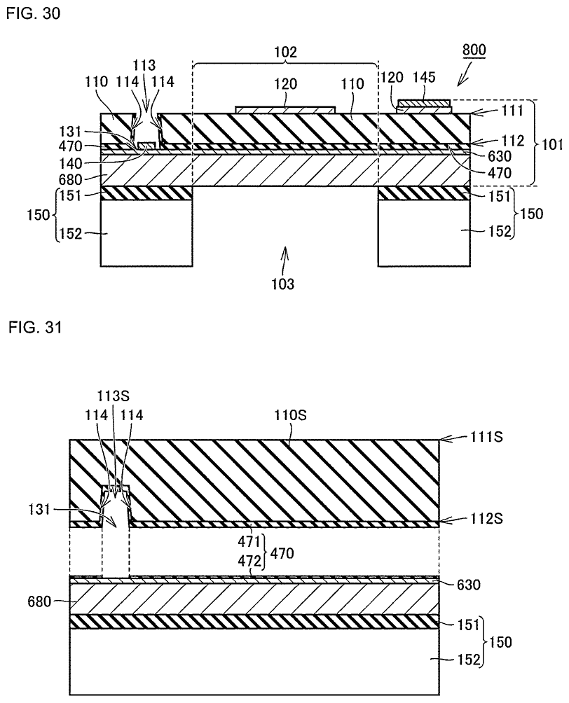

FIG. 30 is a cross-sectional diagram illustrating a piezoelectric element according to a Preferred Embodiment 8 of the present invention. As illustrated in FIG. 30, the piezoelectric element 800 according to Preferred Embodiment 8 of the present invention includes a second electrode layer 630 made of a metallic material and a silicon layer 680 on the opposite surface of the second electrode layer 630 from the piezoelectric layer 110, similar to the piezoelectric element 600 according to Preferred Embodiment 6 of the present invention. In the present preferred embodiment, the bond between the piezoelectric layer 110 and the second electrode layer 630, made of a metallic material, is stronger due to a bonding layer 470 present between the second electrode layer 630 and the piezoelectric layer 110.

The following describes how to produce the piezoelectric element according to Preferred Embodiment 8 of the present invention. First, as illustrated in FIG. 16, on a piezoelectric substrate 110S with a depression 113S made therein a bonding layer 470 is formed in the same or substantially the same manner as in the production of the piezoelectric element 400 according to Preferred Embodiment 4 of the present invention. Then, as illustrated in FIG. 24, a second electrode layer 630 is placed on the silicon layer 680 of the multilayer substrate 104S in the same or substantially the same manner as in the production of the piezoelectric element 600 according to Preferred Embodiment 6 of the present invention.

As in the production of the piezoelectric element 400 according to Preferred Embodiment 4 of the present invention, the bonding layer 470 is made of, for example, silicon oxide (SiO₂). The bonding layer 470 may include multiple layers. The multiple layers may include metal layer(s). If the bonding layer 470 includes multiple layers, the portion of the bonding layer 470 in contact with the second electrode layer 630 may be a layer of native oxide film of the second electrode layer 630. FIG. 31 is a cross-sectional view of a piezoelectric element according to Preferred Embodiment 8 of the present invention in a production process thereof, illustrating a second bonding layer of a multilayer bonding layer about to be bonded to a first bonding layer. This is a drawing of a piezoelectric element according to Preferred Embodiment 8 of the present invention in a production process thereof, illustrating a second bonding layer including multiple bonding layers about to be bonded to a first bonding layer. As illustrated in FIG. 31, a second bonding layer 472 is bonded to a first bonding layer 471, which has already been laid. In bonding the first and second bonding layers 471 and 472 together, the portion of the second electrode layer 630 that will be aligned with the depression 113S in the piezoelectric substrate 110S is cleared of the second bonding layer 472 beforehand so that the second bonding layer 472 will not be aligned with the depression 113S.

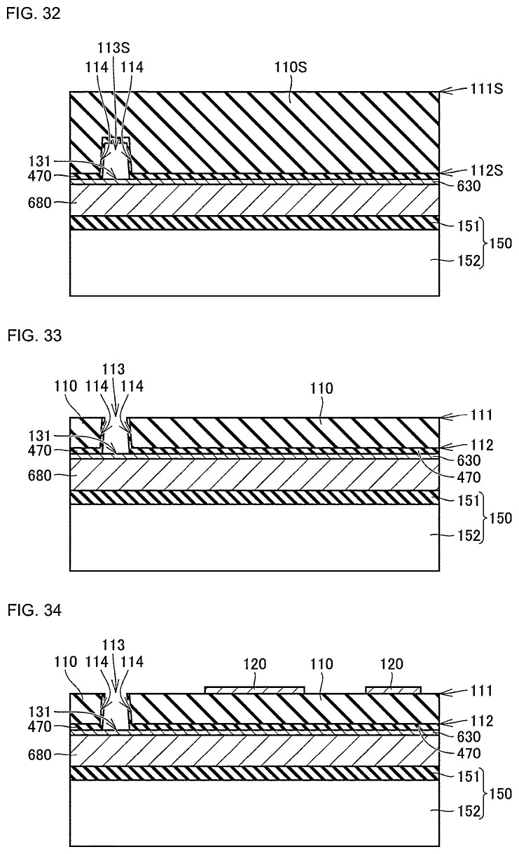

FIG. 32 is a cross-sectional view of a piezoelectric element according to Preferred Embodiment 8 of the present invention in a production process thereof, illustrating a bonding layer on a piezoelectric substrate bonded to a second electrode layer on a multilayer substrate. As illustrated in FIG. 32, the second electrode layer 630 and the piezoelectric substrate 110S are bonded together by, for example, surface activated bonding or atomic diffusion bonding with the bonding layer 470 interposed therebetween. If the bonding layer 470 includes first and second bonding layers 471 and 472 as in FIG. 31, the second electrode layer 630 and the piezoelectric substrate 110S are bonded together with the first and second bonding layers 471 and 472 interposed therebetween.

FIG. 33 is a cross-sectional view of a piezoelectric element according to Preferred Embodiment 8 of the present invention in a production process thereof, illustrating a piezoelectric layer formed by scraping a piezoelectric substrate. As illustrated in FIG. 33, the bottom, to which the bonding layer 470 has been bonded, of the depression 113S is removed together with the bonding layer 470.

FIG. 34 is a cross-sectional view of a piezoelectric element according to Preferred Embodiment 8 of the present invention in a production process thereof, illustrating a first electrode layer being placed. As illustrated in FIG. 34, a first electrode layer 120 is laid on the first surface 111 side of the piezoelectric layer 110.

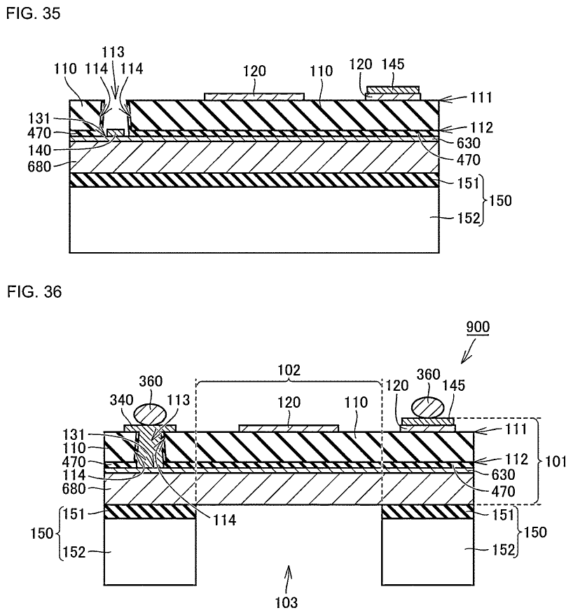

FIG. 35 is a cross-sectional view of a piezoelectric element according to Preferred Embodiment 8 of the present invention in a production process thereof, illustrating coupling electrodes being placed. As illustrated in FIG. 35, a coupling electrode 140 and an outer coupling electrode 145 are formed in the same or substantially the same manner as for the piezoelectric element 100 according to Preferred Embodiment 1 of the present invention. Then, lastly, an opening 103 is created to finish the piezoelectric element 800 according to Preferred Embodiment 8 of the present invention illustrated in FIG. 35.

### Preferred Embodiment 9

The following describes a piezoelectric element according to Preferred Embodiment 9 of the present invention. The piezoelectric element according to Preferred Embodiment 9 of the present invention differs from the piezoelectric element 800 according to Preferred Embodiment 8 of the present invention primarily in the structure of the coupling electrode. The following description, therefore, omits description of the same or substantially the same structural details as for the piezoelectric element 800 according to Preferred Embodiment 8 of the present invention.

FIG. 36 is a cross-sectional diagram illustrating a piezoelectric element according to Preferred Embodiment 9 of the present invention. The piezoelectric element 900 according to Embodiment 9 of the present invention includes through hole 113 plugged with the coupling electrode 340, like the piezoelectric element 300 according to Preferred Embodiment 3 of the present invention. This improves the peel strength of the coupling electrode 340 with respect to the second electrode layer 630.

In the above description of preferred embodiments, the structural elements, features, and configurations may be combined unless mutually exclusive.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric element comprising:
a piezoelectric layer including a first surface, a second surface facing the first surface, and a through hole extending all the way from the first surface to the second surface;
a first electrode layer on the first surface;
a second electrode layer on a second surface side of the piezoelectric layer, at least a portion of the second electrode layer facing the first electrode layer with the piezoelectric layer interposed therebetween and including a coupling area that meets the through hole in a region of the second electrode layer not facing the first electrode layer; and
a coupling electrode on the coupling area, wherein
between the coupling area and a surface of the second electrode layer on a piezoelectric layer side excluding the coupling area, a difference in position is about 5 nm or less.

2. The piezoelectric element according to claim 1, wherein the through hole widens from the first surface towards the second surface.

3. The piezoelectric element according to claim 2, wherein the through hole widens continuously from the first surface towards the second surface.

4. The piezoelectric element according to claim 1, wherein the coupling electrode is spaced away from an inner surface of the through hole.

5. The piezoelectric element according to claim 1, wherein the through hole is plugged with the coupling electrode.

6. The piezoelectric element according to claim 1, wherein in reactive ion etching with CF₄ gas, an etching rate of a material of the second electrode layer is higher than an etching rate of a material of the piezoelectric layer.

7. The piezoelectric element according to claim 1, wherein
the piezoelectric layer includes an alkali niobate or alkali tantalate compound;
an alkali metal or metals in the alkali niobate or alkali tantalate compound is at least one of lithium, rubidium, or cesium; and
the second electrode layer primarily includes silicon.

8. The piezoelectric element according to claim 7, wherein the piezoelectric layer includes lithium niobate.

9. The piezoelectric element according to claim 7, wherein the piezoelectric layer includes lithium tantalate.

10. The piezoelectric element according to claim 7, wherein the second electrode layer primarily includes single-crystal silicon.

11. The piezoelectric element according to claim 1, wherein
the piezoelectric layer includes lithium niobate; and
the second electrode layer includes a metallic material.

12. The piezoelectric element according to claim 1, wherein a bonding layer is provided between the piezoelectric layer side of the second electrode layer excluding the coupling area and the piezoelectric layer.

13. The piezoelectric element according to claim 12, wherein the bonding layer includes silicon oxide.

14. The piezoelectric element according to claim 11, wherein a silicon layer is provided on an opposite surface of the second electrode layer from the piezoelectric layer.

15. The piezoelectric element according to claim 1, further comprising:
a base supporting a multilayer body including at least the first electrode layer, the piezoelectric layer, and the second electrode layer; wherein
the base is on a second electrode layer side of the multilayer body and has a ring shape in alignment with a periphery of a surface of the multilayer body on a base side when viewed in a direction of stacking of layers in the multilayer body.

16. The piezoelectric element according to claim 15, wherein
the base includes a silicon oxide layer in contact with the second electrode layer; and
the second electrode layer includes single-crystal silicon doped with a chemical element that lowers electrical resistivity of the second electrode layer.

17. A piezoelectric element comprising:
a piezoelectric layer including a first surface, a second surface facing the first surface, and a through hole extending all the way from the first surface to the second surface;
a first electrode layer on the first surface;
a second electrode layer on a second surface side of the piezoelectric layer, at least a portion of the second electrode layer facing the first electrode layer with the piezoelectric layer interposed therebetween and including a coupling area that meets the through hole in a region of the second electrode layer not facing the first electrode layer; and
a coupling electrode on the coupling area; wherein
the through hole widens from the first surface towards the second surface.

18. The piezoelectric element according to claim 17, wherein the through hole widens continuously from the first surface toward the second surface.

19. A method for producing a piezoelectric element, the method comprising:
making, by etching, a depression on a second primary surface side of a piezoelectric substrate including a first primary surface and a second primary surface facing the first primary surface;
forming a piezoelectric layer including a first surface, a second surface facing the first surface, and a through hole extending all the way from the first surface to the second surface by grinding the piezoelectric substrate from a first primary surface side and then polishing the substrate to expose the first surface and at the same time create the through hole as a hole defined by an inner surface of the depression by removing a bottom of the depression;
placing a second electrode layer on a second surface side of the piezoelectric layer such that at least a portion of the second electrode layer meets the through hole; and
placing a first electrode layer on a first surface side of the piezoelectric layer such that at least a portion of the first electrode layer faces the second electrode layer with the piezoelectric layer therebetween.
